(19) United States
(12) Patent Application Publication
(10) Pub. No.: US 2011/0206909 A1
(43) Pub. Date: Aug. 25, 2011

(54) COATINGS FOR SUPPRESSING METALLIC WHISKERS

(75) Inventor: Ofer Sneh, Boulder, CO (US)

(73) Assignee: SUNDEW TECHNOLOGIES LLC, Broomfield, CO (US)

(21) Appl. No.: 13/125,811

(22) PCT Filed: Oct. 29, 2009
(86) PCT No.: PCT/US2009/062484

§ 371 Date: Apr. 25, 2011

Related U.S. Application Data
(60) Provisional application No. 61/109,947, filed on Oct. 31, 2008.

(51) Int. Cl. B32B 15/04; C23C 16/40; B32B 3/10; C09D 7/00

(52) U.S. Cl. 428/195.1; 427/255.395; 427/248.1; 428/457; 106/287.19; 106/287.17

(57) ABSTRACT

A coating is formed by depositing the coating on a metallic feature at a deposition temperature. Subsequently, the deposited coating and the metallic feature are cooled below the deposition temperature. The coating is chosen such that this cooling step causes the coating to induce a tensile stress in the metallic feature sufficient to substantially suppress the growth of metallic whiskers on that metallic feature. The coating thereby acts to suppress the growth of metallic whiskers.

### FIELD OF THE INVENTION

This invention relates to the manufacturing of electronics components and, more particularly, to the suppression of metallic whisker growth on metal features comprising tin, zinc, cadmium, and their alloys.

### BACKGROUND OF THE INVENTION

Spontaneously growing whiskers often appear on tin (Sn), cadmium (Cd) and zinc (Zn) parts and finishes (“features”). Tin features are extensively used in the electronic industry to provide electrically conductive, corrosion protected soldering surfaces. For decades, successfully implemented lead-tin features were able to suppress tin whiskers down to marginal and acceptable levels. Recently implemented environmental protection regulations phased out the usage of lead in mainstream electronics, consequently resurrecting the risks of tin-whisker driven electrical circuit failure. Unfortunately, today's advanced, sub-millimeter pitch circuitry is much more prone to whisker-driven failure than its half-a-century-ago prior predecessors.

Metallic whiskers grow from their base, and sometimes have kinked shapes. Tin whiskers are typically single crystals, a few micrometers in diameter, and up to several millimeters in length. Research indicates that whiskers are driven by compressive stress to extrude through cracks in the native tin oxide. Chemically or thermally driven compressive stress in the range of only 10 Megapascals (MPa) were correlated with the growth of whiskers.

Several mechanisms can cause compressive stress to form in a metallic feature. Chemically driven compressive stress buildup was attributed to copper (or other atoms with great solubility in tin such as zinc) diffusion from base metal into the tin features wherein intermetallic copper-tin compounds, mostly Cu₆Sn₅, grow at the copper-tin interface and along grain boundaries. In particular, grain boundaries swelling with the growth of higher volume Cu₆Sn₅ compressively squeeze the grains to extrude whiskers. At the same time, Cu₆Sn₅ growth at the tin-copper interface builds up an effective barrier to progressively lower the buildup of compressive stress and related growth of whiskers. Chemically driven compressive stress buildup also correlates with the swelling of the grain boundaries due to oxidation.

Similarly, thermally driven buildup of compressive stress correlates with the temperature cycling of tin features over substrates with small Coefficients of Thermal Expansion (CTEs). For example, pure tin feature with CTE of 23 parts-per-million per degree Celsius (ppm/° C.) over Alloy 42 (A42, 42:58 Ni:Fe alloy) with CTE of 4.3 ppm/° C. produces as much as 1.5 MPa of compressive stress per degree C. of temperature rise driving stress relieving whiskers growth. Consequently, tin deficient features produce as much as 1.5 MPa of tensile stress per degree C. of temperature cooldown driving stress relieving buildup of cracks and recessed areas. Progressively, the thermally driven process levels off, correlated with the growing density of whiskers, cracks and recessed areas.

Additional compressive stress mechanisms include intrinsic buildup of stress during electroplating and a variety of mechanical stresses such as torques, warping, bending, denting, scratching and marring.

Lead free tin features are also prone to a β→α phase transformation from white tin to gray tin known as “tin pest.” Tin pest (also known by the name “tin plague” or “tin disease”) is a spontaneous phase transition that turns on at temperatures lower than 13 degrees Celsius (° C.). Alfa (α) tin nucleates at the surface of tin features and subsequently propagates into the bulk. A 21% volume increase essentially disintegrates tin features or tin parts into powder. Tin pest is a serious reliability problem in cold weathers and space applications. Like in the case of whiskers, tin pest was adequately suppressed in lead-tin features and parts, and resurfaced when lead was excluded.

With the exclusion of lead-tin features the electronics industry tumbled into uncertainty wherein looming failures from tin-whiskers and tin-pest could no longer be ruled out. Instead, risk mitigation practices were adapted. While all pure tin features have the potential for whisker growth, bright-electroplated tin features have the highest density and longest whiskers. In particular, a poorly controlled bright-tin plating process can lead to early formation of whiskers. Process parameters that effect whisker formation include excessive brightener concentration, high current densities, and/or low operating temperatures. In contrast, most matte and satin features significantly reduce the growth of tin whiskers. Improved plating processes are designed to reduce the residual stress in the plated tin.

Barrier layers (such as nickel), underplated between the base metal and the tin feature, are also applied to suppress the formation of copper-tin inter metallic compounds (IMCs). Additionally, high diffusivity of tin into nickel and lower diffusivity of nickel into tin, effectively build up tensile stress within the tin feature to effectively cancel compressive stress buildup and whisker growth. However, the low CTE of nickel (α_{Ni}=13 ppm/° C.), compared to tin (α_{Sn}=23 ppm/° C.) gives rise to an adverse thermally driven buildup of compressive stress of 0.78 MPa per ° C. As a result, temperature variations quickly erase the benefit of using nickel barrier layers.

Thin plating (less than 1 micrometer (μm) or thicker plating (greater than 20 μm) may also reduce tin whisker formation. Unfortunately, the thin plating may reduce the ability of the feature to serve other necessary functions such as to resist corrosion. On the other hand, while higher thickness may reduce internal stress in the plate, mechanical damage and/or long term growth of IMCs may still initiate whisker formation at somewhat delayed time.

Fusing or heat-treating parts that have pure tin plating is thought to increase grain size and reduce internal stresses that may induce the growth of tin whiskers. Accordingly, reflow of tin features is an effective whisker suppressor. However, this improvement might be short lasting, affected by the substrate, the environment, or by any number of other potential variables. It has been observed that scratches on pure tin features can become sites of whisker growth. In addition, bending a tin finished surface in such a way as to cause a compressive load in the feature has been observed to increase whisker formation. Similarly, additional mechanical stress may form during component soldering. Therefore, handling the parts after reflow may compromise the effectiveness of this mitigation strategy. Reflow might also compromise the reliability of subsequent parts assembly.

Annealing (below the 232° C. melting temperature of tin) may suppress whisker growth. Annealing involves heating and cooling a structure in such a manner as to: (1) soften a cold-worked structure by recrystallization or grain growth, or both; (2) soften an age-hardened alloy by causing a nearly complete precipitation of the second phase in relatively coarse form; (3) soften certain age-hardened alloys by dissolving the second phase and cooling rapidly enough to obtain a supersaturated solution; and (4) relieve residual stress. There has been speculation that heating parts to 125° C. for a few seconds may reduce the risk of tin whisker growth. Unfortunately, the factors related to the effectiveness of annealing on whisker formation are not known/studied and conclusive results are not available. Likewise, conditions such as temperature, hold time, and heating and cooling rates that are required to sufficiently remove the residual stress in tin plated features are elusive. Experimental results suggest that, with “annealing,” the IMC grows uniformly and not preferentially along grain boundaries, thus imparting very limited stress. Formation of copper-tin IMC layers may also serve as a barrier for diffusion of substrate elements into the tin deposit, which might be stress inducers. Copper-tin IMCs grown under ambient temperature has different morphology and tends to grow into grain boundaries causing more compressive stress.

Conformal coatings (CC) combine whisker containment with across-the-board insulation to reduce the risk of failure. Adhesion strength and material toughness in combination with application thickness determine the CC effectiveness. If the coatings are too thin or otherwise soft, whiskers may poke through the CC to intersect another conductive surface. If the CC fails to contain whisker formation, the effectiveness of a conformal coat in providing protection against electrical leakage and corrosion will be compromised. A puncture site may provide an increased opportunity for excessive leakage currents that can produce transient or permanent failures. Another concern is the potential for whiskers to produce minor delamination of the conformal coating from the circuit board, the resulting capillary space potentially providing a void for condensation of the water vapor molecules that may diffuse through the coating material, thereby promoting galvanic corrosion. Further, emerged whiskers that break loose could end up as conductive debris in other areas of the circuit boards. For certain parts, currently used CCs may not provide effective protection due to the inability of these conformal coating to completely cover all exposed plated surfaces. For instance, pin grid arrays (PGAs), ball grid arrays (BGAs), chip scale packages (CSP), connectors, and other low profile devices may have uncoated surfaces even after a CC is applied. Previously applied CCs suffer from several deficiencies such as low strength and hardness, poor adhesion, high internal stress, and very large CTEs. Both the high internal stress and the large CTEs impose large compressive stress on tin features further aggravating the tendency to grow whiskers. For example, following a 60° C. curing, Uralane 5750 (α_{U}=90 ppm/° C.) on tin will develop 7 MPa compressive stress. Additionally, CCs such as Parylene, urathanes, acrylics, silicones and epoxies degrade in humid ambient to become softer and less adherent. Accordingly, these conformal coatings only make it worse in terms of the compressive stress, the driving force for whiskers. Also, they are too soft and poorly adhering to provide reliable containment.

In US Patent Application Serial No. 2003/0025182, Abys et al. attempts to produce an intrinsically tensile stressed tin layer by applying a modified tin electroplating process. This premeditated tensile stress may inhibit whisker growth by offsetting the buildup of compressive stress. However, using modified electroplating with and without underplate layers, Abys et al could only produce meager 2-3 MPa of tensile stress. These low levels may not be sufficient to impact the substantially higher levels of chemically and thermally driven compressive stresses that a metallic feature is likely to experience over its lifetime.

The looming prospects of premature, tin-whiskers driven failure is catastrophic. In particular, future components and circuit boards with denser circuitry and smaller pitches further escalate the failure risks posed by whiskers and whisker debris. Current risk mitigation practices are ambiguous and inconsistent, and are, therefore, unacceptable for many critical applications of electronics such as military, aerospace, automotive, medical, industrial control, critical power systems, computer servers, central data storage hubs and critical telecommunications, altogether comprising more than 30% of the annual worldwide market. There is, therefore, a need for whisker suppression methods with the dependability of lead-tin. These methods should dependably and consistently eliminate the buildup of compressive stress. Preferably, these methods should also suppress tin pest.

### SUMMARY OF THE INVENTION

Embodiments of the present invention address the above-identified needs by providing Whisker-cap coatings (WCCs) that act to induce a large tensile stress on an underlying metallic feature. This tensile stress substantially suppresses the growth of metallic whiskers on that feature.

In accordance with an aspect of the invention, a coating is formed by depositing the coating on a metallic feature at a deposition temperature. Subsequently, the deposited coating and the metallic feature are cooled below the deposition temperature. The coating is chosen such that this cooling step causes the coating to induce a tensile stress in the metallic feature sufficient to substantially suppress the growth of metallic whiskers on that metallic feature.

In accordance with another aspect of the invention, an apparatus comprises a metallic feature and a coating deposited on the metallic feature. Here to, the coating is chosen such that depositing the coating on the metallic feature at a deposition temperature and then cooling the coating and metallic feature below the deposition temperature causes the coating to induce a tensile stress in the metallic feature sufficient to substantially suppress the growth of metallic whiskers on the metallic feature.

In accordance with one of the above-identified embodiments of the invention, a WCC is deposited on a metallic substrate to suppress whisker growth on that substrate. The WCC is a laminate comprising an adhesion layer, a plurality of alternating middle layers, and an outermost cap layer. The adhesion layer is formed by initially hydroxylating the metallic feature surface and then utilizing atomic layer deposition (ALD) to deposit of Al₂O₃ thereon. The middle layers are formed by the ALD of alternating layers of Al₂O₃ and TiO₂ or alternating layers of Al₂O₃ and TiO₃C₂H₄. Lastly, the outermost layer is formed by the ALD of Ti₉Al₂O₂₁. Advantageously, the above described WCC induces several hundred Megapascals of tensile stress on the underlying metallic feature, which, in turn, acts to suppress the growth of metallic whiskers both directly under the WCC and in proximity thereto. Moreover, the WCC has adhesion, hardness, yield strength, barrier, and other properties that are conducive to its use on electronic devices.

### BRIEF DESCRIPTION OF THE DRAWINGS

These and other features, aspects, and advantages of the present invention will become better understood with regard to the following description, appended claims, and accompanying drawings where:

FIGS. 1A and 1B show schematics of a reaction and coating growth sequence in accordance with an illustrative embodiment of the invention for depositing a WCC;

FIGS. 2A and 2B show schematics of a reaction sequence in accordance with an illustrative embodiment of the invention for depositing TiO₃C₂H₄;

FIG. 3A shows a scanning electron microscope (SEM) image of an uncoated tin feature after 18 months in accelerated whisker growth conditions;

FIG. 3B shows an SEM image of a tin feature coated with a WCC after 18 months in accelerated whisker growth conditions; and

FIGS. 4A-4C show SEM images of a cross-sectioned tin feature and WCC at various magnifications.

### DETAILED DESCRIPTION OF THE INVENTION

The present invention will be described with reference to illustrative embodiments. For this reason, numerous modifications can be made to these embodiments and the results will still come within the scope of the invention. No limitations with respect to the specific embodiments described herein are intended or should be inferred.

As used herein, the term “metallic feature” is intended to encompass any structure or layer that is formed of metal. A metallic layer may therefore be disposed on another metallic object and still be defined as a separate metallic feature herein. As a result, the term “metallic feature” would include, as just a few examples, a tin finish that overlays a copper electrical trace on a printed circuit board (PCB), a tin finish that overlays a copper leadframe in an integrated circuit, a tin finish that overlays a copper electrical connector or pin, and a zinc finish that overlays a steel floor tile.

Embodiments in accordance with aspects of the present invention utilize a WCC that is deposited over a metallic feature in order to suppress the growth of metallic whiskers from that metallic feature. The WCC is chosen to have a CTE substantially smaller than that of the metallic feature and to strongly adhere to the metallic feature. The deposition process is then performed at an elevated temperatures (e.g., 125° C.), and, at the completion of the deposition process, the parts are allowed to cool down to room temperature. After the cooldown, the CTE mismatch and strong adhesion between the WCC and metallic feature result in the buildup of tensile stress at the metal feature interface. This tensile stress substantially suppresses the growth of metallic whiskers from the metallic feature.

The amount of tensile stress induced in the metallic film can be estimated by calculation. If it is assumed, for example, that the metallic feature is tin and has a CTE of α_{Sn}=23 ppm/° C., and that the WCC has a CTE of α_{WCC}=5 ppm/° C. then, when the WCC cools down from 125° C. to room temp (25° C.), the 100° C. change in temperature will induce a tensile stress of:

$${σ}_{m} = {ɛ}_{m} \frac{{E}_{f}}{1 - {v}_{f}} = \frac{100 \times ( 23 - 5 ) \times {10}^{- 6} \times 150 \times {10}^{9}}{( 1 - 0.24 )} = 355 MPa \qquad ( 1 )$$

where E_{f} and v_{f} are the Young's modulus and Poisson ratio, respectively, of the WCC layer. The Young's modulus of a ceramic WCC is typically (depending on the selection of materials and laminated structures) in the range E_{f}=130-250 GPa (150 GPa was used in this example). Such a ceramic WCC also exhibits Poisson ratio in the range of v_{f}=0.21-0.27 (0.24 was used in the example). Accordingly, the tin feature is preloaded with hundreds of MPa of tensile stress. WCC adhesion on tin in the range of 1,500-3,000 PSI prevents delamination and assures that this stress loading is uniform across the entire metallic feature. The WCCs high yield strength (about 2-3 GPa) also assures that the WCC will remain elastic and will not permanently deform under normal operating conditions.

Notably, as indicated earlier, metallic whiskers may be induced in tin by as little as about 10 MPa of compressive stress. For this reason, a preloading above about 100 MPa of tensile stress in the metallic feature (i.e., an order of magnitude higher than the compressive stress required for whisker formation) will likely be sufficient to offset the chemical, mechanical, and thermal buildup of compressive stress over the useful lifetime of the part.

Of course, in addition to having appropriate CTEs, Young's moduli, Poisson ratios, and adhesion properties, other factors must also be considered when designing the WCC. The WCC will, for example, preferably be relatively hard in order to protect the device. In addition, the WCC will need to be electrically insulating in the vast majority of applications. Conformal and durable insulation of all surfaces provide an additional layer of protection from whiskers related electrical failure. The WCC should also provide corrosion resistance as well as environmental protection, blocking the diffusion of H₂O, O₂, CO₂, NO, Na+, SiO₄²⁻, and other such corrosives. Lastly, the WCC needs to deposit in a highly conformal manner so that all the exposed surfaces of the underlying electronic device are uniformly covered and protected.

The present inventor has, in fact, produced WCCs that meet the stringent guidelines described above. Deposition of these WCCs comprises several processing steps. First, commercially available cleaning equipment and formulations are utilized to scrub the tin, zinc or cadmium metallic features of debris, fluxes, salts, greases, waxes and other common contaminations. For example, high pressure nozzle cleaner SMT600CL (MannCorp) employing standard aqueous cleaning cycles sequencing EF105 and citric acid based biodegradable cleans (NuGen Tech), distilled water (DI-water) rinsing, and clean air drying may be utilized. The selection of cleaning agents and cleaning parameters should be compatible with the metal features as well with all other materials present on the circuit board assemblies.

Following the wet clean, drying is facilitated as known in the art. For example, the circuit boards are immersed in a 50:50 isopropyl-alcohol:DI-water solution and then processed with a combination of dry air and convection oven drying. Following drying, the circuit boards are loaded into the WCC deposition chamber. In the preferred embodiment a large capacity atomic layer deposition (ALD) chamber is utilized. Initially, the parts are warmed up to the deposition temperature (e.g., 125° C.), and outgassed under high N₂ flow, low pressure conditions. Typically, flow and pressure of 3-5 standard liters per minute (sLm) and 0.10 Torr, respectively, are applied.

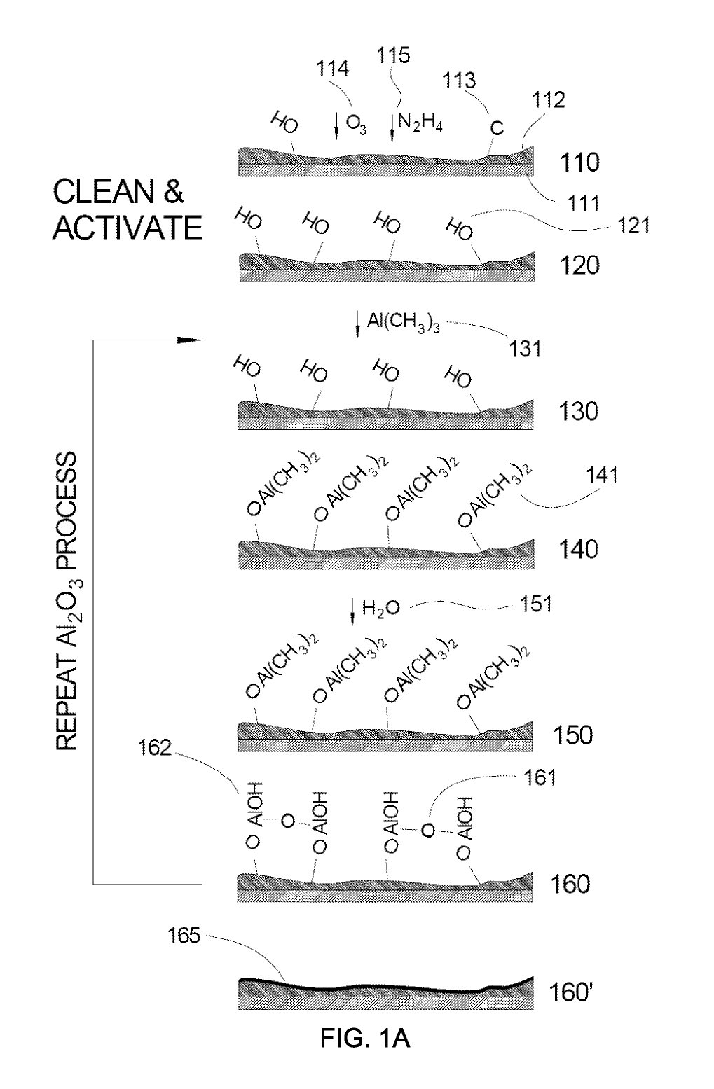

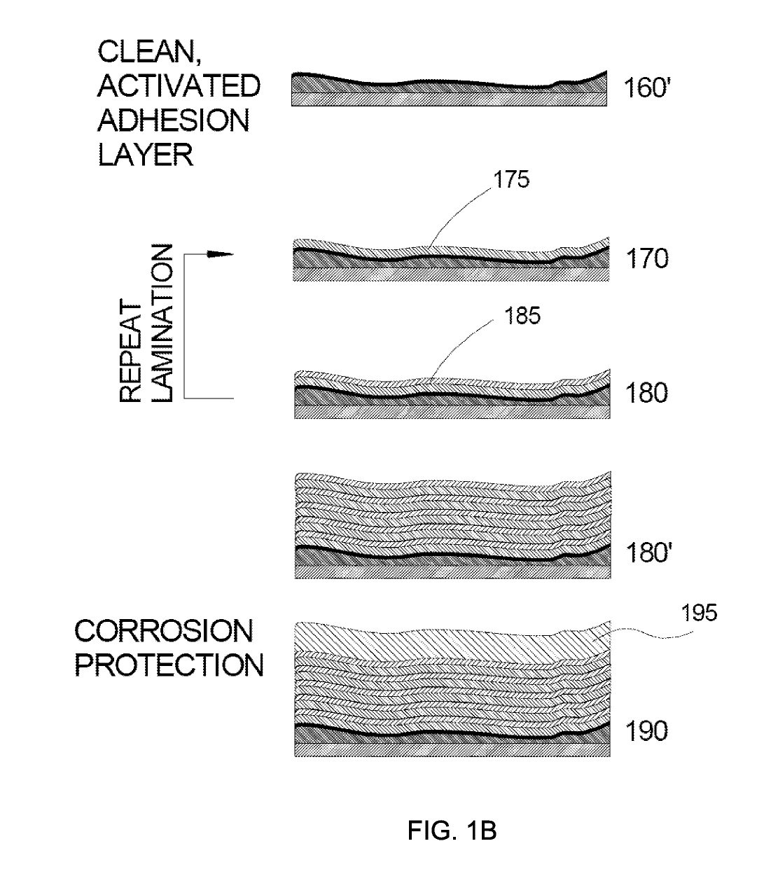

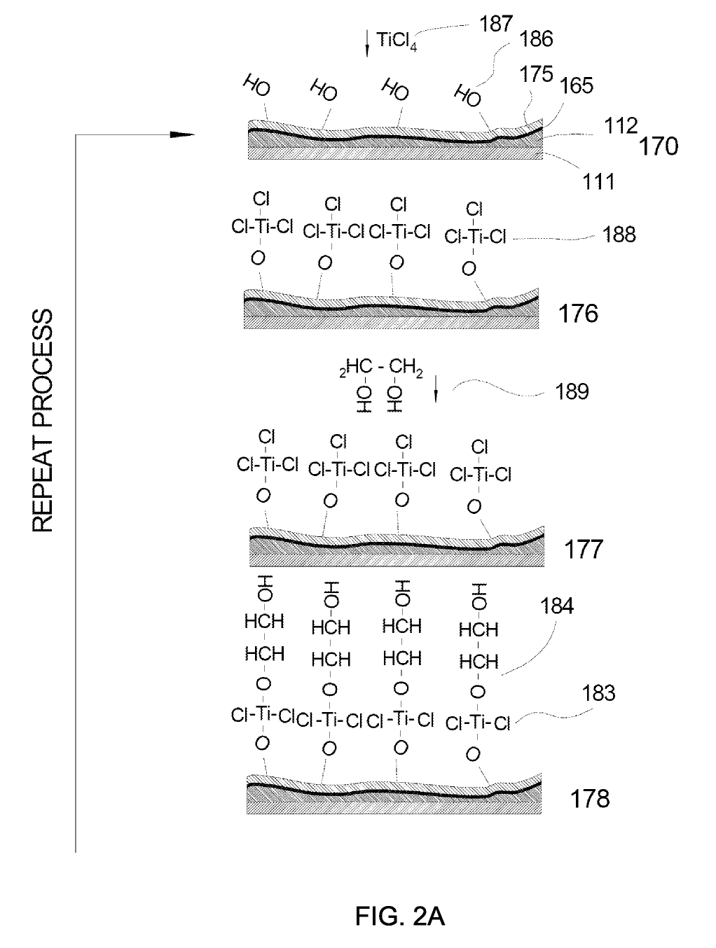

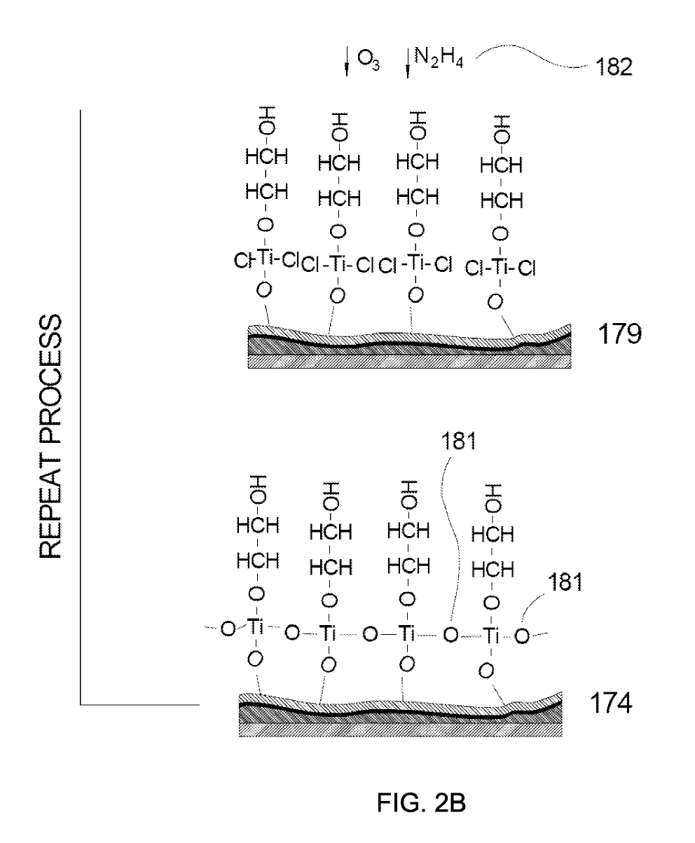

The remaining steps are shown by film stacks at various stages of processing FIGS. 1A, 1B, 2A, and 2B. As depicted by film stack 110 in FIG. 1A, ozone (O₃) 114 and hydrazine (N₂H₄) 115 are flowed into the process chamber to produce a highly oxidizing and hydroxylating ambient in the process chamber in order to ensure fully oxidized and fully hydroxylated termination 121 of the tin, zinc or cadmium metallic feature 112, while at the same time also burning and volatilizing any traces of organic contamination such as carbon atom 113. The resultant film stack appears as shown by film stack 120, where element 111 is the base metal. This process is also very efficient in cleaning and hydroxylating most plastic, ceramic, and metallic surfaces, and removing contamination out of pores. For example, O₃ at a flow of 200 standard cubic-centimeters per minute (sccm) is mixed with 5 sccm of N₂H₄ for 20 seconds at 1 Torr.

In the next step, as indicated by film stack 130, the freshly hydroxylated surfaces 121 are exposed to reactive gas such as trimethylaluminum (Al(CH₃)₃) vapor 131. In a saturating process the hydroxylated surfaces are exchanged with dimethylaluminum (Al(CH₃)₂) surface species 141 and eliminate a methane by-product (as shown by film stack 140). The excess of unused Al(CH₃)₃ is purged out of the process chamber. Next, as shown by film stack 150, the Al(CH₃)₂ terminated surface 141 is exposed to a saturating process to convert the Al(CH₃)₂ surface into cross-linked Al₂O₃ 161 terminated by hydroxyl species 162 (as shown by film stack 160). This process is accomplished by exposure to H₂O 151 or other oxidizers such as O₃/N₂H₄, NO/N₂H₄, H₂O₂, or NO/NH₄OH. Following the saturation of the oxidizing/hydroxylating step, the excess reactants are again purged out of the process space. Then the process sequence per panels 130, 140, 150, 160 is iterated to grow a 1-5 nanometers (nm) thick adhesion layer 165, yielding the film stack 160′. Typical process conditions are: 0.5-1 Torr pressures during the reactive gas exposures; purge flow rates of 3-5 sLm; 0.15-0.3 Torr pressures during purge; and exposures of 5×10¹⁷/sqft (“sqft”=square foot) and 2-5×10¹⁸/sqft. of the Al(CH₃)₃ and the oxidizer, respectively. Reactive gas exposures are normalized for 1 square foot of circuit board.

Alternative adhesion layers such as various aluminum-titanium oxide compositions or various zirconium-tantalum oxide compositions are also useful wherein typically TiCl₄, ZrCl₄ and TaCl₅ are used as the Ti, Zr and Ta sources, respectively. When implementing chlorine containing precursors, care should be taken to ensure the minimization of residual chlorine in the film. Properly grown adhesion layers over properly cleaned and activated features promote the growth of the WCC without any intrinsic stress, as per complete wetting and layer by layer growth of the film starting from the interface. Accordingly, the predictable and reproducible tensile stress is thermally driven when the circuit boards are cooled down from the process temperature. During the growth of adhesion layers, purges are extended to minimize and suppress possible traces of a continuous, non step-by-step, chemical vapor deposition (CVD) process. CVD processes could promote a competing film initiation by nucleation and its related, undesired intrinsic compressive stress.

Following the completion of adhesion layer 165, a nano-laminated film stack 180′, typically 30-450 nm in thickness is grown in a stepwise ALD fashion, as shown in the schematics in FIG. 1B. The laminated barrier layer preferably implements high ceramic contents layer 175, layered with different ceramic layers, or with ceramic-polymer composite layers 185 (as shown by film stacks 170, 180 and 180′). For example, a film stack may comprise alternating 19:1 nm Al₂O₃:TiO₂ layers. In this case, an ALD sequence of Al(CH₃)₃/purge/oxidizer/purge is pursued to grow a 19 nm layer followed by the growth of 1 nm of TiO₂ with the ALD sequence of TiCl₄/purge/oxidizer/purge. The bi-layer is then repeated to grow the desired thickness.

Alternatively, a laminated ceramic ceramic-polymer stack is grown. For example, a 18:2 nm Al₂O₃:TiO₃C₂H₄ is applied by sequentially laminating 18 nm of Al₂O₃ with a Al(CH₃)₃/purge/oxidizer/purge process sequence followed by a 2 nm of TiO₃C₂H₄ (Ticone) using the process of TiCl₄/purge/C₂H₄(OH)₂/purge/N₂H₄—O₃/purge.

Nevertheless, when forming such ceramic-polymer layers, it is frequently necessary to neutralize leftover residual reactivity within the ceramic-polymer layers with a hydrazine rich N₂H₄/O₃ mixture in order to titrate any residual reactivity. As indicated in FIGS. 2A and 2B, when forming TiO₃C₂H₄, the hydroxyl terminated surface 186 of ceramic layer 175 is reacted with TiCl₄ 187 to attach TiCl₃ and eliminate HCl by-product (as shown by film stacks 170 and 176). Next, as shown by film stack 177, the —TiCl₃ terminated surface is exposed to ethylene glycol (C₂H₄(OH)₂) 189. As a result, —O—C₂H₄OH 184 attaches to the surface titanium, as illustrated by film stack 178. However, due to the bulky nature of —O—C₂H₄OH, some reactive sites 183 are inaccessible. These residually reactive leftover are detrimental to the stability and performance of the films. Therefore, the preferred embodiment utilizes a highly reactive, hydroxylating Catalyzing Reactively Induced Surface Processes (CRISP) process 182, namely exposure to O₃ and N₂H₄ 182, to react away chlorine 183, as well as other reactive leftover species (as shown by film stacks 179 and 174). CRISP reactions are described in, for example, U.S. Pat. No. 7,250,083 to Sneh, which is hereby incorporated by reference. Preferably, reactive sites cleanup also results in additional cross-linking 181, to further improve the quality and the properties of the film. Similarly, reactive —Al—CH₃ sites were found in aluminum-oxide-polymer-ceramics, Alucone. Again, CRISP steps added to each ALD cycle effectively eliminated the leftover residual reactivity and its related instability, moisture sensitivity and inconsistency.

Likewise, many other mixed ceramics polymer combinations (“polycones” or organic-inorganic polymers), were all found to be prone to leftover residual reactivity that required reactivity elimination ALD steps. In addition to cross linking oxidation, other reactivity titration steps successfully implemented other cross linking atoms such as nitrogen, sulfur, selenium, etc. Preferably, hydrogen containing processes also provided for titration of reactive site that cannot cross link. While reactivity titration is feasible with H₂O, ozone, H₂S, NH₃ etc., these conventional processes were found to be too slow for practical use. Alternatively, CRISP processes were found to be adequately fast for practical and cost effective use. Additionally, mixed ceramic-polymer ALD processes also required very effective purge cycles with high flow of pre-heated inert gas such as N₂ preheated to 150° C. High effective purge was achieved at flow rates of several sLm and low pressures. For example, 5 sLm and pressure below 100 mTorr and a purge time of 700 milliseconds (ms) were effective for a TiO₃C₂H₄ (ethylene-ticone) ALD process inside a 3 liter ALD process chamber. In another example 3 sLm and 50 mTorr and a purge time of 500 ms were effective during the growth of Al₂O₅C₃H₆ (propylene-alucone) ALD process inside a 3 liter process chamber.

Polycone lamination with ceramic layers effectively increases the crack toughness and the crack propagation toughness of WCCs by a factor of 2-4 as compared to laminated ceramics. In addition, thin polycone layers in the range of 2-25 nm were added on top of WCC layers, as well as other ALD layers or directly on parts to create highly hydrophobic, water repellant finish.

Again referring to FIG. 1B, following the completion of the laminated barrier layer 180′, a corrosion protection layer 195 is grown to a thickness of 10-50 nm to ensure corrosion resistance of the entire stack (as shown by film stack 190). For example, a layer of SiO₂ ALD film is grown from the sequence of (C₄H₁₄N₂Si)/purge/CH₃N₂H₃—O₃/purge (where C₄H₁₄N₂Si is Bis(diethylamino)silane). Alternatively, a 9:1 composite of titanium aluminum oxide, Ti₉Al₂O₂₁ is grown from the sequences of TiCl₄/purge/H₂O/purge and Al(CH₃)₃/purge/oxidizer/purge.

Process pressures, flows and exposures for metal precursors and oxidants are similar to the ones described above with the exception of C₄H₁₄N₂Si exposure being 2×10¹⁸/sqft.

WCCs formed in the above-described manner achieved strong adhesion to metal features and common circuit board assemblies. Table I summarizes the adhesion strengths that were measured using conventional adhesion pull tests for several ceramic and ceramic-polymer WCCs over several commonly used substrates. As indicated earlier, strong adhesion values are believed to be important to tin-whiskers suppression. WCC cohesion to the tin feature provides evenly distributed tensile stress pre-load. Compressive stress including intrinsic buildup of stress during electroplating is thereby offset.

In addition, the above-described WCCs also had other properties conducive to their use on electronic devices in suppressing tin whiskers. Measured Young's moduli were 130-182 GPa and measured hardnesses were 7.8-9.8 GPa. Yield strengths were about 2-3 GPa (suggesting that the WCCs are highly elastic). Conformality was near 100%. Lastly, the WCCs were determined to form a hermetic seal over the metallic feature, being pinhole free and exceeding the Military Specification MIL-STD 883E for environmental barriers and resistance to corrosion.

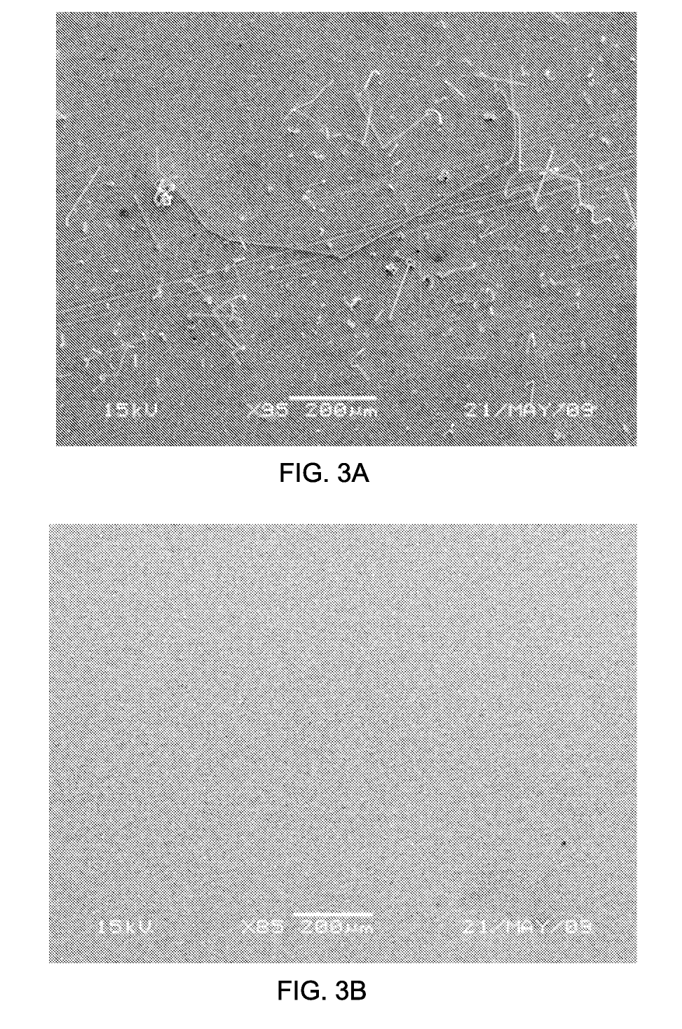

The WCCs ability to substantially suppress the extrusion of tin whisker features was also carefully verified. FIG. 3A shows an SEM image of a tin substrate as a function of time without a WCC while FIG. 3B shows an identical tin substrate (in fact, the coated half of the same substrate) as a function of time with a WCC. The data in FIGS. 3A and 3B represent over 18 months of accelerated whiskers growth testing. As indicated in FIG. 3B, the WCC inhibits further evolution of small, pre-existing nodules and stops the development of new tin formations and the growth of whiskers. In contrast, as indicated in FIG. 3A, the uncoated tin forms a wild and dense distribution of metallic whiskers.

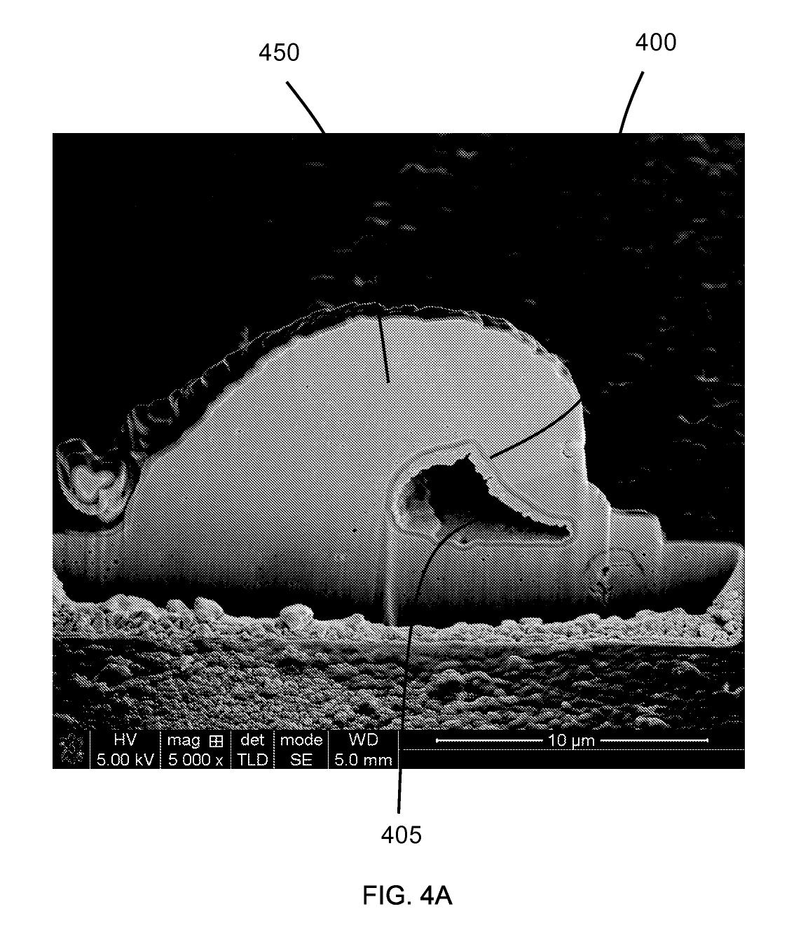

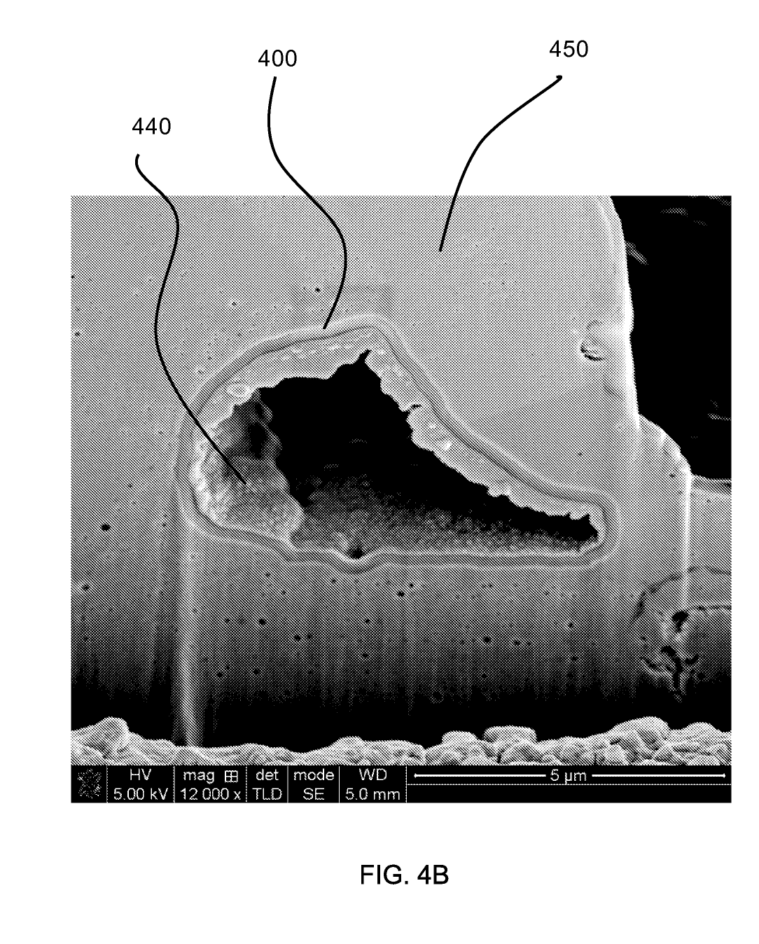

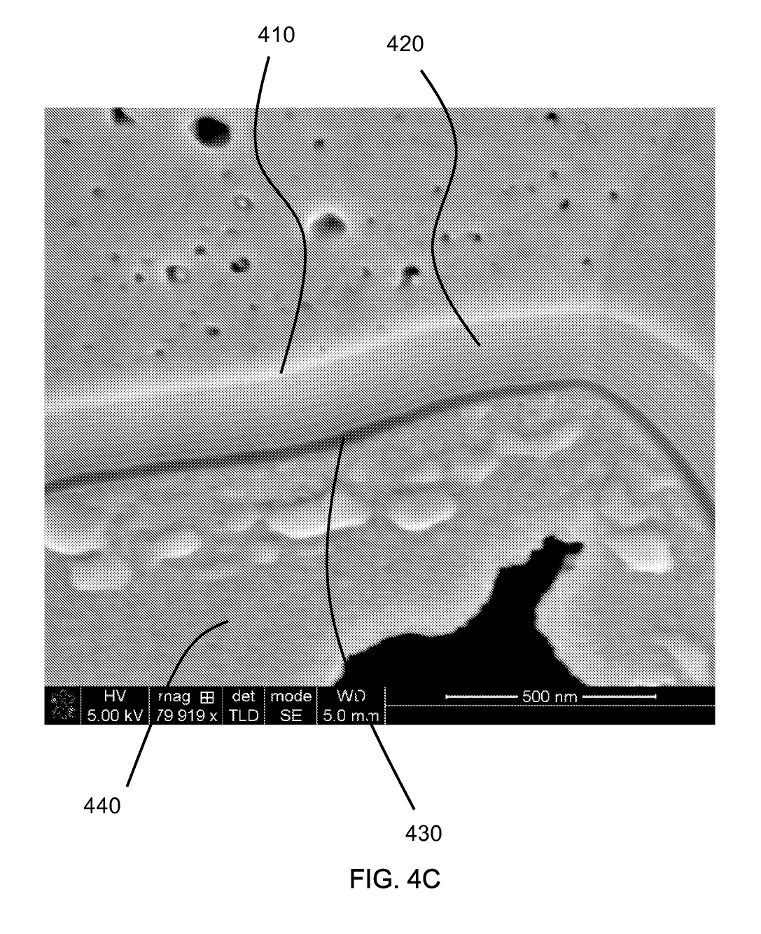

Notably, the effect of the preloaded tensile stress developed by the WCC extends into the tin feature, thereby having an effect on the formation of whiskers even where the WCC does not directly contact the tin. For example, FIG. 4A displays the SEM image of a WCC coated tin whisker. Focused Ion Beam (FIB) was used to precisely cross-section the whisker to highlight the coating 400. Note the adhesion layer 410, laminated barrier 420 and corrosion protection layer 430. Following the preparation of the cross-section (and the creation of some ion milling debris 440), tin was exposed by the cross section at 450. However, this exposed tin did not grow whiskers. This suppression of whiskers growth on an accelerated whiskers growth substrate proximate to, but not covered by a WCC, supports the theory that suppression of tin whisker growth is related to the tensile stress pre-load, rather than to the physical barrier (which was removed by the FIB from area 450.

TABLE 1
Whisker-Cap adhesion to common metal features
and circuit board assembly surfaces

| Substrate | Application | Adhesion pull strength (psi) |
|---|---|---|
| Immersion tin | PCB feature | 1,700 |
| Bright electroplated | PCB feature | >1,500 |
| tin | | |
| Gold | PCB feature | >1,400 |
| Copper | PCB feature | >1,600 |
| FR4 | PCB material | >2,500 |
| R/Flex | PCB material | 1,200 |
| Kapton | PCB material | 1,000 |
| Thermosetting | PEM package | >2,500 |
| epoxies | material | |
| 3M Scotch-Weld | IC attachment | >3300 |
| 2216 B/A | | |

WCCs in accordance with aspects of the invention also help suppress the β→α tin pest phase transition. For example, tin pest is driven by a slight, entropy driven free energy gain of G=H−ST=−2,100+7.4×T that is overwhelmingly offset by the strain energy (exerted on the WCC by the α-tin) of a 21% volume expansion of the β→α tin phase transition. For example, conservatively assuming a critical size α-tin nuclei of 10 nm, a 21% volume expansion represents a 6.5% vertical expansion. This meager δ=6.5 A corresponds to a vertical strain of ε_{WCC}=0.0065 out of a 0.10 μm thick WCC film. The strain energy is given by:

$$U = \frac{{σ}_{v} δ}{2 a} = \frac{{E}_{f} {δ}^{2}}{2 {a}^{2} ( 1 - {v}_{f} )} = \frac{1.5 \times {10}^{7} \times {( 6.5 \times {10}^{- 8} )}^{2}}{2 \times {( {10}^{- 5} )}^{2} ( 1 - 0.24 )} = 417 Joul \text{/} {cm}^{2} \qquad ( 2 )$$

where the film Young's modulus is E_{f}=150 GPa=1.5×10⁷N/cm² and the film Poisson ration is v_{f}=0.24. Assuming tin-pest nucleation size of 0.01 μm=10⁻⁶ cm, film thickness of a=0.1 μm=10⁻⁵ cm and δ˜0.065×0.01 μm=6.5×10⁻⁸ cm. Accordingly, the strain energy corresponds to 10⁻¹⁸ cm³ of tin. Given the density of 7.287 gm/cm³ and the molar mass of tin m=118.71 gm the 10 nm cube of tin corresponds to 6×10⁻²⁰ mole. The Gibbs free energy of β→α conversion of tin is G=H−ST=−2,100+7.4T Joules/mole. Accordingly, at −40° C. the free energy is G=−375 Joule/mole. However, the strain energy for the equivalent expansion of a 10 nm cube nuclei is 7 GJoules/mole, far dominating the energy gain from the phase transition. Accordingly, WCC suppresses the growth of tin pest.

Advantageously, processes in accordance with aspects of the invention are amenable to relatively simple contact masking and liftoff techniques. Masking can be achieved by dipping, brushing and dubbing. For example, AZ P150 Protective Coating is typically used as a lift-off mask. This commercially available lift-off coating is easy to apply and cures at 100° C. High CTE on the order of 150 ppm/° C. generates 2.4 GPa of tensile stress. Under these stress levels, the protective coatings yield and develop micro cracks. As a result, the overlaying WCC also micro-crack to facilitate an easier and faster removal of the masking. Given the WCC thickness range of 50-500 nm the lift off tends to form nicely defined openings.

WCC coated solder joints can be dissolved and reworked by standard desoldering techniques. When the solder melts, WCC coatings disintegrate. Accordingly straightforward rework and repair procedures follow. Preferably, WCC coated components with masked leads are soldered in place of the failed components. This procedure result in WCC protected feature on components leads portions that are not wet by the solder.

It should again be emphasized that the above-described embodiments of the invention are intended to be illustrative only. Other embodiments can use different types and arrangements of elements for implementing the described functionality. These numerous alternative embodiments within the scope of the appended claims will be apparent to one skilled in the art.

Moreover, all the features disclosed herein may be replaced by alternative features serving the same, equivalent, or similar purposes, unless expressly stated otherwise. Thus, unless expressly stated otherwise, each feature disclosed is one example only of a generic series of equivalent or similar features.

What is claimed is:

1. A method for suppressing the growth of metallic whiskers on a metallic feature, the method comprising the steps of:
depositing a coating on the metallic feature at a deposition temperature; and
cooling the deposited coating and the metallic feature below the deposition temperature;
wherein the coating is chosen such that the cooling step causes the coating to induce a tensile stress in the metallic feature sufficient to substantially suppress the growth of metallic whiskers on the metallic feature.

2. The method of claim 1, wherein the metallic feature comprises tin, zinc, or cadmium.

3. The method of claim 1, wherein the coating has a coefficient of thermal expansion substantially lower than that of the metallic feature.

4. The method of claim 1, wherein the coating induces a tensile stress in the metallic feature of at least about 100 Megapascals.

5. The method of claim 1, wherein the metallic feature comprises tin, and the coating further substantially suppresses the conversion of beta tin into alfa tin in the metallic feature.

6. The method of claim 1, wherein the coating has an adhesion pull strength from the metallic feature of at least about 1,400 pounds per square inch.

7. The method of claim 1, wherein the coating provides corrosion resistance to the metallic feature meeting Military Specification MIL-STD-883E.

8. The method of claim 1, wherein the coating provides environmental barrier protection to the metallic feature meeting Military Specification MIL-STD-883E.

9. The method of claim 1, wherein the coating has a conformality of greater than about 95%.

10. The method of claim 1, wherein the coating has a yield strength higher than about one Gigapascal.

11. The method of claim 1, wherein the coating is substantially electrically insulating.

12. The method of claim 1, wherein the coating comprises a ceramic material.

13. The method of claim 1, wherein the coating comprises a ceramic-polymer material.

14. The method of claim 1, wherein the step of depositing the coating comprises atomic layer deposition.

15. The method of claim 14, wherein the atomic layer deposition utilizes a CRISP reaction.

16. The method of claim 14, wherein the atomic layer deposition utilizes hydrazine.

17. The method of claim 14, wherein the atomic layer deposition utilizes monomethylhydrazine.

18. The method of claim 1, wherein the coating comprises Al₂O₃.

19. The method of claim 18, wherein the Al₂O₃ is at least partially deposited using Al(CH₃)₃ and an oxidizer.

20. The method of claim 1, wherein the coating comprises TiO₂.

21. The method of claim 20, wherein the TiO₂ is at least partially deposited using TiCl₄ and an oxidizer.

22. The method of claim 1, wherein the coating comprises TiO₃C₂H₄.

23. The method of claim 22, wherein the TiO₃C₂H₄ is at least partially deposited using TiCl₄ and an oxidizer.

24. The method of claim 22, wherein the TiO₃C₂H₄ is at least partially deposited using C₂H₄(OH)₂.

25. The method of claim 1, wherein the coating is a laminate comprising a plurality of layers.

26. The method of claim 25, wherein the coating comprises alternating layers of Al₂O₃ and TiO₂.

27. The method of claim 25, wherein the coatings comprises alternating layers of Al₂O₃ and TiO₃C₂H₄.

28. The method of claim 1, wherein the coating comprises an adhesion layer in contact with the metallic feature.

29. The method of claim 28, wherein the adhesion layer is deposited at least in part using Al(CH₃)₃ and an oxidizer.

30. The method of claim 28, wherein the adhesion layer is deposited at least in part using an oxidizer and at least one of TiCl₄, ZrCl₄, and TaCl₄.

31. The method of claim 28, wherein the adhesion layer is deposited at least in part using at least one of O₃, N₂H₄, H₂O₂, NO, and NH₄OH.

32. The method of claim 1, further comprising the step of cleaning and activating the metallic feature before depositing the coating.

33. The method of claim 32, wherein the cleaning and activating step comprises at least partially hydroxylating the metallic feature.

34. The method of claim 32, wherein the cleaning and activating step utilizes at least one of O₃ and N₂H₄.

35. The method of claim 1, wherein the coating comprises an outermost cap layer comprising SiO₂.

36. The method of claim 1, wherein the coating comprises an outermost cap layer comprising Ti₉Al₂O₂₁.

37. An apparatus comprising:
a metallic feature; and
a coating deposited on the metallic feature, the coating chosen such that depositing the coating on the metallic feature at a deposition temperature and then cooling the coating and metallic feature below the deposition temperature causes the coating to induce a tensile stress in the metallic feature sufficient to substantially suppress the growth of metallic whiskers on the metallic feature.

38. The apparatus of claim 37, wherein the apparatus comprises a printed circuit board, integrated circuit, or electrical connector.

39. The apparatus of claim 37, wherein the apparatus comprises a steel bracket or a steel floor tile

40. A method of forming a film, the method comprising sequentially performing a plurality of reaction sequences in a process space, each reaction sequence comprising the steps of:
introducing a first reactant into the process space;
purging substantially all of the first reactant from the process space;
introducing a second reactant into the process space;
purging substantially all of the second reactant from the process space; and
introducing at least one of hydrazine, monomethylhydrazine, and dimethylhydrazine into the process space.

41. The method of claim 40, wherein the film comprises an organic-inorganic polymer, the first reactant is a metal halide, and the second reactant is a diol.

42. The method of claim 40, wherein the film comprises TiO₃C₂H₄, the first reactant is TiCl4, and the second reactant is C₂H₄(OH)₂.

43. The method of claim 40, wherein the film comprises Al₂O₅C₃H₆, the first reactant is Al(CH₃)₃, and the second reactant is C₃H₆(OH)₂.

44. The method of claim 40, wherein the film comprises Al₂O₅C₂H₄, the first reactant is Al(CH₃)₃, and the second reactant is C₂H₄(OH)₂.

45. The method of claim 40, wherein O₃ is introduced into the process space with the at least one of hydrazine, monomethylhydrazine, and dimethylhydrazine.

46. The method of claim 40, wherein the film is formed on a substrate, and the substrate is at least partially hydroxylated prior to sequentially performing the plurality of reaction sequences.

47. An apparatus comprising a film, the film formed at least in part by performing a plurality of reaction sequences in a process space, each reaction sequence comprising the steps of:
introducing a first reactant into the process space;
purging substantially all of the first reactant from the process space;
introducing a second reactant into the process space;
purging substantially all of the second reactant from the process space; and
introducing at least one of hydrazine, monomethylhydrazine, and dimethylhydrazine into the process space.
